(19) United States
(12) Patent Application Publication
(10) Pub. No.: US 2026/0282765 A1
(43) Pub. Date: Sep. 17, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventor: Hui-Lin Wang, Taipei City (TW)

(73) Assignee: UNITED MICROELECTRONICS CORP., Hsin-Chu City (TW)

(21) Appl. No.: 19/178,829

(22) Filed: Apr. 14, 2025

(30) Foreign Application Priority Data
Mar. 17, 2025 (TW) 114109830

(51) Int. Cl. H10N 70/00; H10B 63/00; H10W 46/00

(52) U.S. Cl. CPC H10N 70/063; H10B 63/30; H10N 70/023; H10N 70/821; H10N 70/841; H10N 70/8833; H10W 46/00; H10W 46/301

(57) ABSTRACT

A method for fabricating a resistive random access memory (RRAM) includes the steps of first providing a substrate having an alignment mark region and a RRAM region, forming an interlayer dielectric (ILD) layer on the substrate, forming a contact plug in the ILD layer of the RRAM region, forming a first bottom electrode (BE) layer on the RRAM region and the alignment mark region, and then removing the first BE layer and the ILD layer on the alignment mark region to form a trench.

### BACKGROUND OF THE INVENTION

### Field of the Invention

The invention relates to a semiconductor device, and more particularly to a resistive random access memory (RRAM) device.

### Description of the Prior Art

Non-volatile memory devices have the advantages of retaining data even if the electrical power is being cut off, hence non-volatile memory devices have been widely used in most appliances today for maintaining proper operation of the electronic products. Currently, a popular non-volatile memory device being developed today is referred to as resistive random access memory (RRAM), which has the advantages of low voltage and short erase time under write operation, long memory duration, no damage under read operation, multiphase memory, simple structure, and small size. With all these benefits, RRAM devices are likely to be used in various personal computers and electronic equipment in the coming future.

In integrated circuits, RRAM is a merging technology applied for the next generation non-volatile memory devices. Specifically, RRAM is a memory structure having a resistive random access memory array, in which each of the resistive random access memory units uses resistance values to store one bit of data instead of electrical potentials. In particular, each of the resistive random access memory units include a resistance material layer that could be used to adjust resistance value for demonstrating “0” or “1”.

One approach to optimize RRAM array is to minimize its size as much as possible. Nevertheless, as size of the device decrease, fabrication cost and complexity also increase accordingly. Hence, how to lower the overall cost while maintaining yield of the product has become a major challenge in this field.

### SUMMARY OF THE INVENTION

According to an embodiment of the present invention, a method for fabricating a resistive random access memory (RRAM) includes the steps of first providing a substrate having an alignment mark region and a RRAM region, forming an interlayer dielectric (ILD) layer on the substrate, forming a contact plug in the ILD layer of the RRAM region, forming a first bottom electrode (BE) layer on the RRAM region and the alignment mark region, and then removing the first BE layer and the ILD layer on the alignment mark region to form a trench.

According to another aspect of the present invention, a resistive random access memory (RRAM) includes an interlayer dielectric (ILD) layer on a substrate, a contact plug in the ILD layer, and a bottom electrode on the contact plug. Preferably, the bottom electrode includes a first bottom electrode (BE) layer and a second bottom electrode layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-11 illustrate a method for fabricating a semiconductor device according to an embodiment of the present invention.

### DETAILED DESCRIPTION

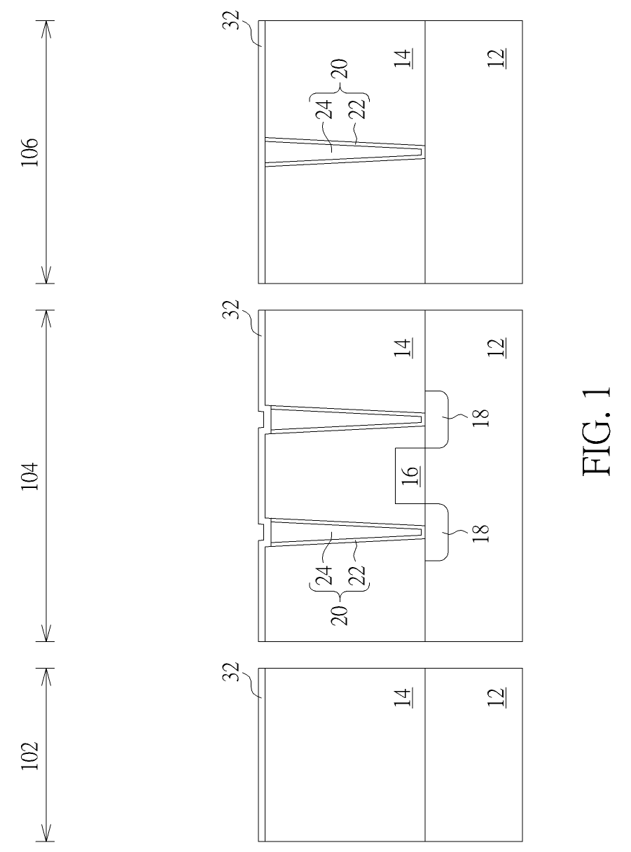

Referring to FIGS. 1-11, FIGS. 1-11 illustrate a method for fabricating a semiconductor device, or more specifically a RRAM device according to an embodiment of the present invention. As shown in FIG. 1, a substrate 12 made of semiconductor material is first provided, in which the semiconductor material could be selected from the group consisting of silicon (Si), germanium (Ge), Si-Ge compounds, silicon carbide (SiC), and gallium arsenide (GaAs), and an alignment mark (AM) region 102, a RRAM region 104, and a logic region 106 are defined on the substrate 12.

Active devices such as metal-oxide semiconductor (MOS) transistors, passive devices, conductive layers, and interlayer dielectric (ILD) layer 14 could also be formed on top of the substrate 12 on both RRAM region 104 and logic region 106. More specifically, planar MOS transistors or non-planar (such as FinFETs) MOS transistors could be formed on the substrate 12, in which the MOS transistors could include transistor elements such as gate structures 16 (for example metal gates) and source/drain regions 18, spacer, epitaxial layer, and contact etch stop layer (CESL). The ILD layer 14 could be formed on the substrate 12 to cover the MOS transistors, and a plurality of contact plugs 20 could be formed in the ILD layer 14 to electrically connect to the gate structures 16 and/or source/drain regions 18 of MOS transistors. Since the fabrication of planar or non-planar transistors and ILD layer is well known to those skilled in the art, the details of which are not explained herein for the sake of brevity.

In this embodiment, the formation of the contact plugs 20 could be accomplished by first conducting a pattern transfer process by using a patterned mask (not shown) as mask to remove part of the ILD layer 14 on the memory region 102 and logic region 104 for forming contact holes (not shown) exposing the source/drain regions 18 underneath. Next, metal or conductive materials including a barrier layer 22 selected from the group consisting of titanium (Ti), titanium nitride (TiN), tantalum (Ta), and tantalum nitride (TaN) and a metal layer 24 selected from the group consisting of tungsten (W), copper (Cu), aluminum (Al), titanium aluminide (TiAl), and cobalt tungsten phosphide (CoWP) are deposited into the contact holes, and then a planarizing process such as chemical mechanical polishing (CMP) process is conducted to remove part of the metal for forming contact plugs 20 or metal interconnections in the contact holes electrically connecting the source/drain regions 18.

Next, another pattern transfer process could be conducted by using a patterned mask to remove part of the contact plugs 20 for forming a recess directly on top of each contact plug 20 while the top surface of the remaining contact plugs 20 is slightly lower than the top surface of the ILD layer 14 on two adjacent sides. Next, a first bottom electrode (BE) layer 32 is formed on the ILD layer 14 on the AM region 102, the RRAM region 104, and the logic region 106 and filling the recesses directly atop the contact plugs 20 completely. In this embodiment, the first BE layer 32 is made of metal such as tantalum (Ta) and the thickness thereof is between 30-50 Angstroms.

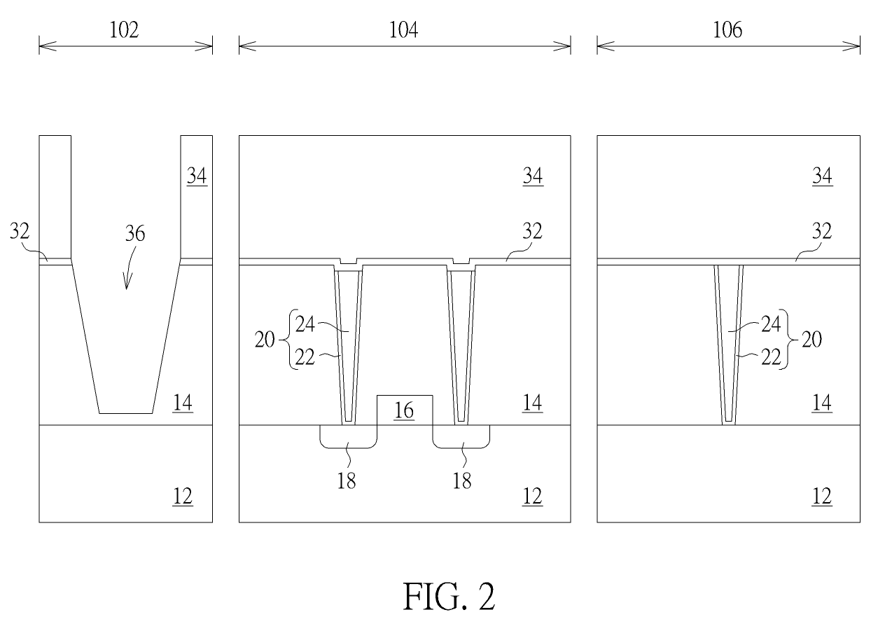

Next, as shown in FIG. 2, a patterned mask 34 such as patterned resist is formed on the first BE layer 32 of the AM region 102, the RRAM region 104, and the logic region 106, in which the patterned mask 34 includes an opening exposing the surface of the first BE layer 32 on the AM region 102. Next, an etching process is conducted by using the patterned mask 34 as mask to remove part of the first BE layer 32 and part of the ILD layer 14 on the AM region 102 for forming a trench 36.

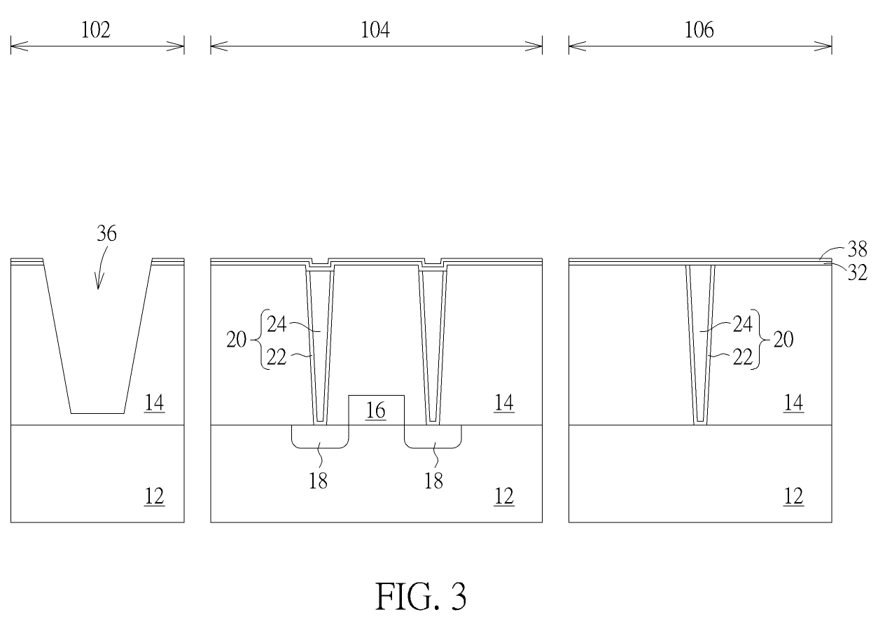

Next, as shown in FIG. 3, the patterned mask 34 is stripped by oxygen gas to expose the first BE layer 32 once more. It should be noted that as the patterned mask 34 is stripped by oxygen gas at this stage, part of the surface of the first BE layer 32 is oxidized at the same time to form a metal oxide layer 38. Since the first BE layer 32 is preferably made of Ta in this embodiment, the metal oxide layer 38 formed on the surface of the first BE layer 32 after stripping the patterned mask 34 through oxygen is made of tantalum oxide (TaO). In this embodiment, the thickness of the first BE layer 32 remained after the oxidation process is between 10-30 Angstroms and the thickness of the metal oxide layer 38 formed on the surface of the first BE layer 32 is between 15-25 Angstroms or most preferably 20 Angstroms.

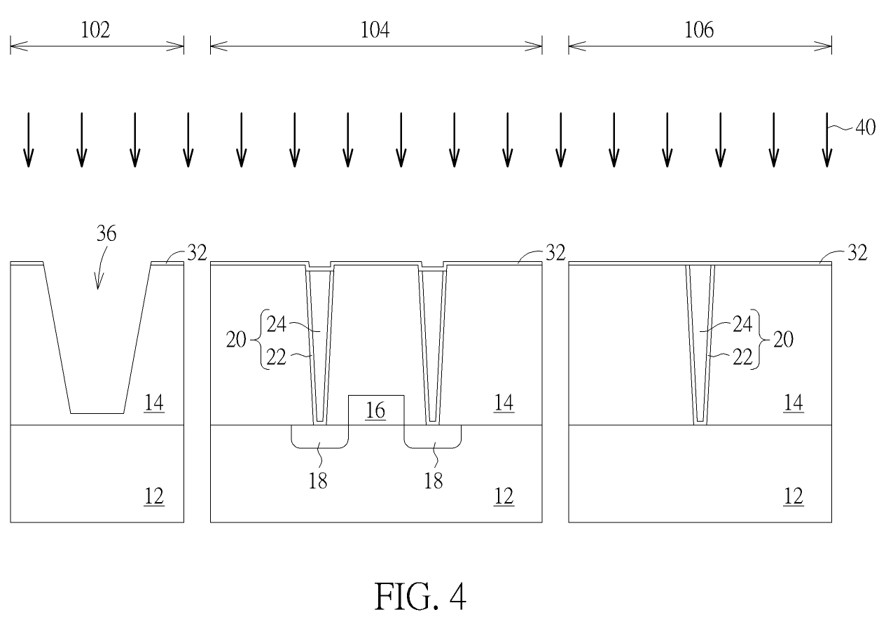

Next, as shown in FIG. 4, a pre-clean process 40 is conducted by using argon (Ar) plasma to remove the metal oxide layer 38 completely. In this embodiment, after the metal oxide layer 38 is removed by the Ar plasma pre-clean process 40, the thickness of the remaining first BE layer 32 is preferably between 10-30 Angstroms.

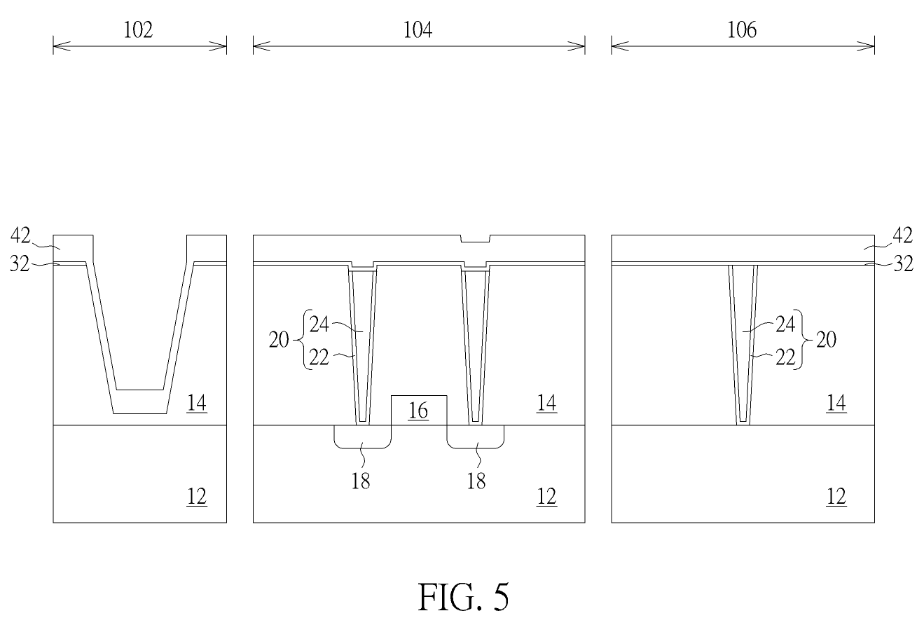

Next, as shown in FIG. 5, a second BE layer 42 is formed on the first BE layer 32, in which the second BE layer 42 is deposited on the surface of the first BE layer 32 on the AM region 102 and into the trench 36 without filling the trench 36 completely. In the meantime, the second BE layer 42 is also deposited on the surface of the first BE layer 32 on both RRAM region 104 and logic region 106. Preferably, the second BE layer 42 includes metal nitride such as tantalum nitride (TaN) and the thickness of the second BE layer 42 is between 100-200 Angstroms.

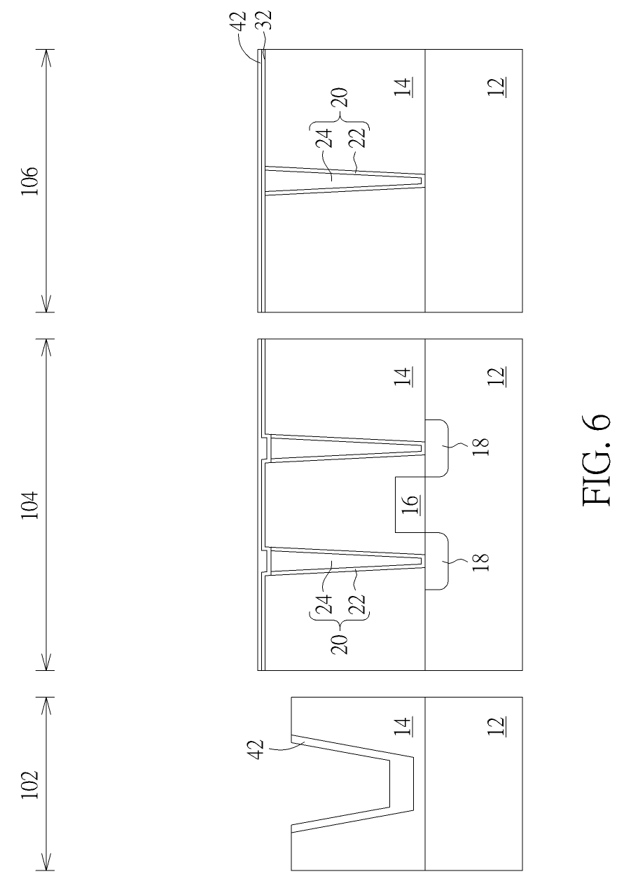

Next, as shown in FIG. 6, a planarizing process such as CMP is conducted to remove part of the second BE layer 42 on the AM region 102, RRAM region 104, and logic region 106 such that the overall thickness of the second BE layer 42 is reduced. Specifically, the planarizing process conducted at this stage removes all the second BE layer 42 and first BE layer 32 adjacent to two sides of the trench 36 and even part of the ILD layer 14 on the AM region 102 and part of the second BE layer 42 on the RRAM region 104 and logic region 106 while the second BE layer 42 within the trench 36 on the AM region 102 is not removed. After part of the second BE layer 42 is removed, the thickness of the remaining second BE layer 42 on the RRAM region 104 and logic region 106 is substantially equal to the thickness of the first BE layer 32 underneath and the top surface of the remaining ILD layer 14 on the AM region 102 would be slightly lower than the top surface of the ILD layer 14 on the RRAM region 104 and logic region 106.

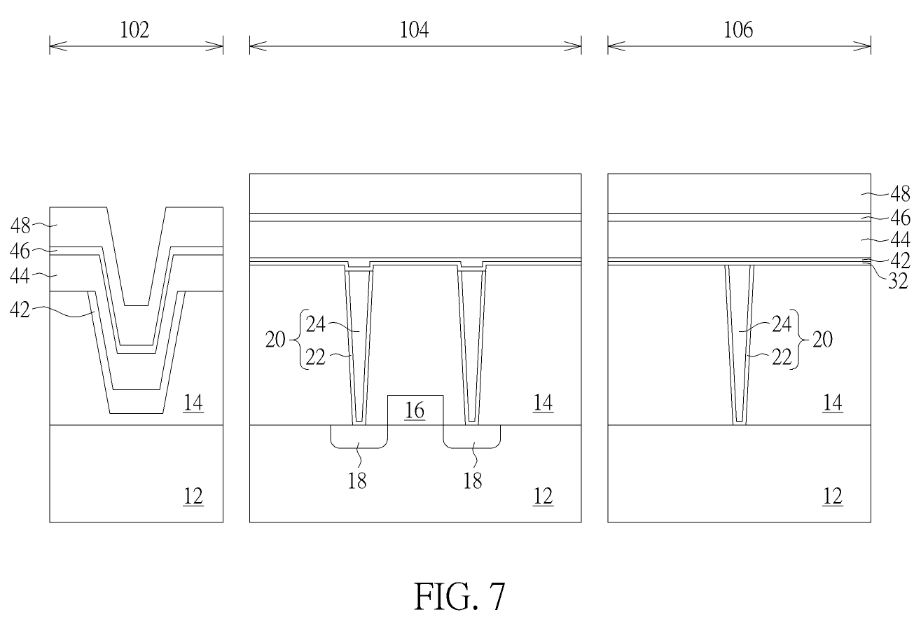

Next, as shown in FIG. 7, a resistor switching layer 44, a capping layer 46, and a top electrode (TE) 48 are formed on the surface of the second BE layer 42. In this embodiment, the resistor switching layer 44 preferably includes a metal nitride layer such as TaO or hafnium oxide (HfO₂), the capping layer 46 includes a metal layer such as iridium (Ir), platinum (Pt), or gold (Au), and the top electrode 48 includes metal nitride such as TaN or TiN.

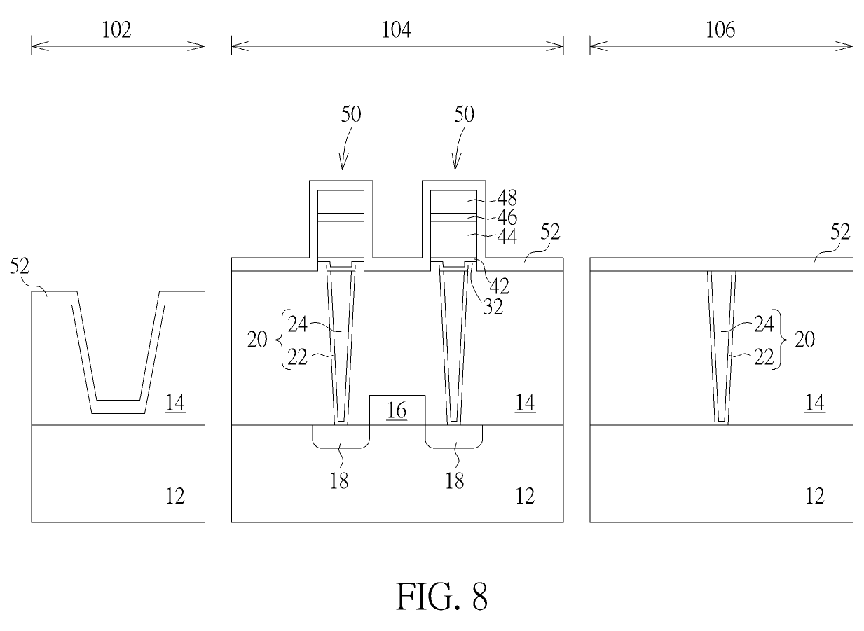

Next, as shown in FIG. 8, one or more etching processes could be conducted by using a patterned mask (not shown) as mask to remove all the top electrode 48, all the capping layer 46, all the resistor switching layer 44, all the second BE layer 42, and all the first BE layer 32 on the AM region 102 and logic region 106 and part of the top electrode 48, part of the capping layer 46, part of resistor switching layer 44, part of the second BE layer 44, and part of the first BE layer 32 on the RRAM region 104. This exposes the surface of the ILD layer 14 on the AM region 102 and logic region 106 and forms a RRAM 50 made of patterned first BE layer 32, patterned second BE layer 42, patterned resistor switching layer 44, patterned capping layer 46, and patterned top electrode 48 on the RRAM region 104. Next, a cap layer 52 is formed on the surface of the ILD layer 14 and into the trench 36 on the AM region 102, surface of the ILD layer 14 and RRAM 50 on the RRAM region 104, and surface of the ILD layer 14 on the logic region 106.

It should be noted that when part of the top electrode 48, part of the capping layer 46, part of the resistor switching layer 44, part of the second BE layer 42, and part of the first BE layer 32 are patterned to form the RRAM 50, it would be desirable to remove part of the ILD layer 14 adjacent to two sides of the RRAM 50 so that the top surface of the remaining ILD layer 14 is slightly lower than the bottom surface of the first BE layer 32 or even lower than the top surface of the contact plugs 20. By doing so, the bottom surface of the cap layer 52 adjacent to two sides of the RRAM 50 afterwards could then be adjusted according to the height of the ILD layer 14. For instance, the bottom surface of the cap layer 52 adjacent to two sides of the RRAM 50 could be even with or slightly lower than the bottom surface of the first BE layer 32 or lower than the top surface of the contact plugs 20, which are all within the scope of the present invention.

Preferably, the cap layer 52 includes dielectric material such as silicon oxycarbide (SiOC), silicon carbon nitride (SiCN), or silicon nitride (SiN) and the etching process conducted for forming the aforementioned RRAM 50 during patterning process could include reactive ion etching (RIE) or ion beam etching (IBE) process, but not limited thereto.

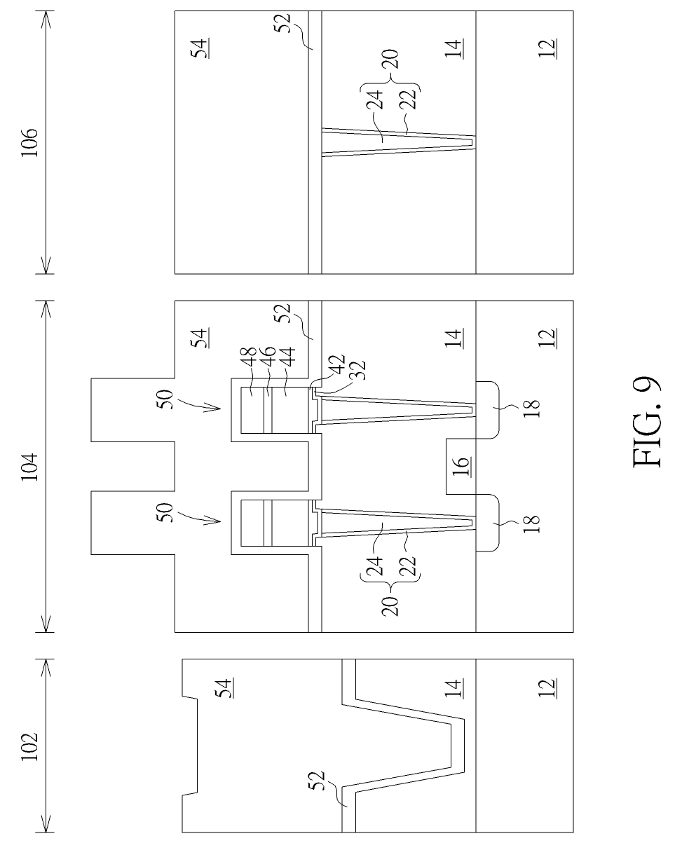

Next, as shown in FIG. 9, a flowable chemical vapor deposition (FCVD) process could be conducted to form an inter-metal dielectric (IMD) layer 54 on ILD layer 14 on the AM region 102, the RRAM region 104, and the logic region 106 to fill the trench 36 completely and cover the RRAM 50. In this embodiment, the IMD layer 54 is preferably made of silicon oxide or ultra-low-k (ULK) dielectric layer including but not limited to for example porous material or silicon oxycarbide (SiOC) or carbon doped silicon oxide (SiOCH).

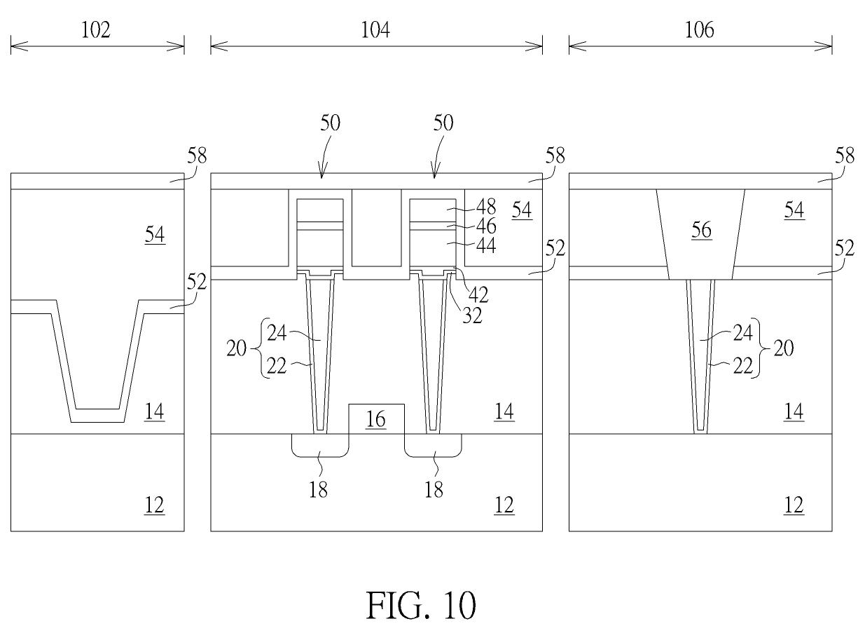

Next, as shown in FIG. 10, a planarizing process such as CMP is conducted to remove part of the IMD layer 54 on the AM region 102, RRAM region 104, and logic region 106 so that the top surfaces of the IMD layer 54 and the cap layer 52 on the RRAM region 104 are coplanar.

Next, a patterned transfer process could be conducted by using a patterned mask (not shown) as mask to remove part of the IMD layer 54 and part of the cap layer 52 on the and logic region 106 for forming a contact hole (not shown) exposing the contact plug 20 underneath. Next, metal or conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact hole, and then a planarizing process such as CMP process is conducted to remove part of the metals for forming a contact plug or metal interconnection 56 in the contact hole electrically connecting the contact plug 20 underneath. Next, a stop layer 58 is formed on the IMD layer 54 on the AM region 102, the RRAM region 104, and the logic region 106. Preferably, the stop layer 58 is made of nitrogen doped carbide (NDC), silicon nitride, silicon carbon nitride (SiCN), silicon oxynitride (SiON), or combination thereof.

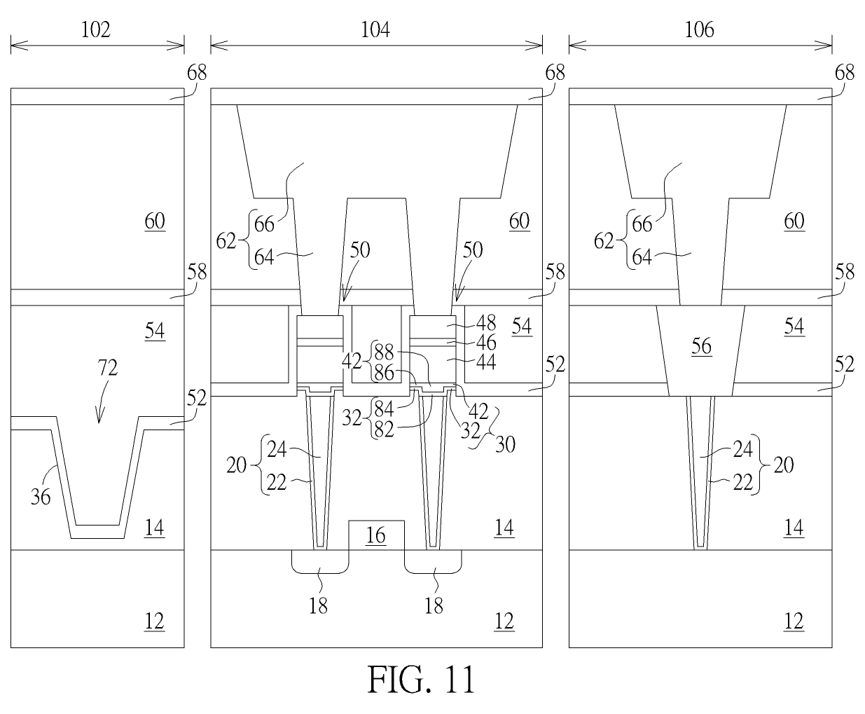

Next, as shown in FIG. 11, another IMD layer 60 is formed on the surface of the stop layer 58 and one or more photo-etching process is conducted to remove part of the IMD layer 60, part of the stop layer 58, and part of the cap layer 52 on the RRAM region 104 and logic region 106 to form contact holes (not shown) exposing the top electrode 48 and metal interconnection 56. Next, conductive materials are deposited into the contact holes and a planarizing process such as CMP is conducted to form a metal interconnection 62 connecting the top electrode 48 and metal interconnection 56 underneath, and another stop layer 68 is formed on the surface of the metal interconnections 62 thereafter. Similar to the aforementioned metal interconnection 56, the metal interconnections 62 could be embedded within the IMD layer 60 according to a single damascene process or dual damascene process. For instance, each of the metal interconnections 62 on the RRAM region 104 and logic region 106 could further include via conductors 64 connecting the RRAM 50 and metal interconnection 56 underneath and a trench conductor 66 atop the via conductors 64. Moreover, each of the metal interconnections 62 could further include a barrier layer and a metal layer, in which the barrier layer could be selected from the group consisting of titanium (Ti), titanium nitride (TiN), tantalum (Ta), and tantalum nitride (TaN) and the metal layer could be selected from the group consisting of tungsten (W), copper (Cu), aluminum (Al), titanium aluminide (TiAl), and cobalt tungsten phosphide (CoWP).

In this embodiment, the IMD layer 60 preferably include an ultra low-k (ULK) dielectric layer including but not limited to for example porous material or silicon oxycarbide (SiOC) and the stop layer 68 preferably includes nitrogen doped carbide (NDC), silicon nitride (SiN), silicon carbon nitride (SiCN), or combination thereof and most preferably includes SiN. This completes the fabrication of a semiconductor device according to an embodiment of the present invention.

Referring again to FIG. 11, FIG. 11 further illustrates a structural view of a semiconductor device according to an embodiment of the present invention. As shown in FIG. 11, the semiconductor device includes an ILD layer 14 disposed on the substrate 12, an alignment mark 72 disposed on the AM region 102, contact plugs 20 disposed in the ILD layer 14 on the RRAM region 104 and logic region 106, RRAMs 50 disposed on the contact plugs 20 of the RRAM region 104, a cap layer 52 disposed on sidewalls of the RRAM 50 and extending to the surface of the ILD layer 14 on the RRAM region 104 and logic region 106, a metal interconnection 56 disposed on the contact plug 20 of the logic region 106, and an IMD layer 54 around the RRAM region 50 and metal interconnection 56.

In this embodiment, the alignment mark 72 on the AM region 102 could include a trench 36 disposed in the ILD layer 14, the cap layer 52 is disposed on the surface of the trench 36 and surface of the ILD layer 14 adjacent to two sides of the trench 36, and the top surface of the ILD layer 14 on the AM region 102 is slightly lower than the top surface of the ILD layer 14 on the RRAM region 104 and logic region 106.

The RRAM 50 disposed on the RRAM region 104 could include a bottom electrode 30 disposed on the contact plug 20, a resistor switching layer 44 disposed on the bottom electrode 30, a capping layer 46 disposed on the resistor switching layer 44, and a top electrode 48 disposed on the capping layer 46. It should be noted that the bottom electrode 30 preferably includes a dual layer structure having a first BE layer 32 and a second BE layer 42 on the first BE layer 32, in which the first BE layer 32 includes metal such as Ta, the second BE layer 42 includes metal nitride such as TaN, the top surface of the first BE layer 32 includes a U-shape, the bottom surface of the second BE layer 42 includes a U-shape, and sidewalls of the first BE layer 32 and second BE layer 42 are aligned.

Specifically, the first BE layer 32 includes a U-shape portion 82 disposed directly on top of the contact plug 20 and two horizontal portions 84 disposed on the ILD layer 14 adjacent to two sides of the U-shaped portion 82. The second BE layer 42 overall includes a T-shape cross-section having a horizontal portion 86 and a vertical portion 88 under the horizontal portion 86, in which sidewalls of the horizontal portion 84 of the first BE layer 32 and the horizontal portion 86 of the second BE layer 42 are aligned. Moreover, the cap layer 82 is disposed on sidewalls of the top electrode 48 and extending downward to the surface of the ILD layer 14, in which the bottom surface of the bottom electrode 30 directly on top of the contact plug 20 could be even with, lower than, or higher than the bottom surface of the cap layer 52 adjacent to two sides of the contact plug 20 and the bottom surface of the bottom electrode 30 adjacent to two sides of the contact plug 20 could be even with or higher than the bottom surface of the cap layer 52 adjacent to two sides of the contact plug 20.

Typically, a material layer made of TaN with a thickness of approximately 200 Angstroms is layered to serve as a bottom electrode before forming an alignment mark during fabrication of a RRAM device in conventional art. Since this bottom electrode material has a high absorption coefficient or low penetration depth thereby posing a disadvantage during fabrication of an alignment mark, the present invention first covers a first BE layer 32 made of Ta on the ILD layer before a trench 36 for forming alignment mark is formed, conducts a photo-etching process to remove part of the first BE layer 32 and part of the ILD layer 14 for forming a trench 36, and then forms a second BE layer 42, a resistor switching layer 44, a capping layer 46, and a top electrode 48 accompanied by patterning process to form a RRAM. Since the Ta metal has a substantially higher penetration rate than conventional TaN, it would be desirable to improve the success rate for forming a trench 36 which is then used for serving as an alignment mark in the later process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a resistive random access memory (RRAM), comprising:
providing a substrate having an alignment mark region and a RRAM region;
forming an interlayer dielectric (ILD) layer on the substrate;
forming a contact plug in the ILD layer of the RRAM region;
forming a first bottom electrode (BE) layer on the RRAM region and the alignment mark region; and
removing the first BE layer and the ILD layer on the alignment mark region to form a trench.

2. The method of claim 1, further comprising:
using a patterned mask to remove the first BE layer and the substrate for forming the trench;
stripping the patterned mask; and
performing a pre-clean process.

3. The method of claim 2, further comprising using argon (Ar) plasma to perform the pre-clean process.

4. The method of claim 1, further comprising:
forming a second BE layer on the first BE layer ;
forming a resistor switching layer on the second BE layer;
forming a top electrode on the resistor switching layer;
patterning the top electrode, the resistor switching layer, the second BE layer, and the first BE layer;
forming a cap layer on the top electrode and the ILD layer;
forming a first inter-metal dielectric (IMD) layer around the cap layer;
forming a second IMD layer on the first IMD layer; and
forming a metal interconnection in the second IMD layer to connect to the top electrode.

5. The method of claim 4, further comprising forming the second BE layer in the trench and on the first BE layer of the RRAM region.

6. The method of claim 4, further comprising planarizing the second BE layer before forming the resistor switching layer.

7. The method of claim 4, further comprising:
removing the top electrode, the resistor switching layer, and the second BE layer on the alignment mark region; and
forming the cap layer in the trench.

8. The method of claim 4, wherein the second BE layer comprises metal nitride.

9. The method of claim 1, wherein the first BE layer comprises metal.

10. A resistive random access memory (RRAM), comprising:
an interlayer dielectric (ILD) layer on a substrate;
a contact plug in the ILD layer; and
a bottom electrode on the contact plug, wherein the bottom electrode comprises:
a first bottom electrode (BE) layer; and
a second bottom electrode layer.

11. The resistive random access memory of claim 10, further comprising:
a resistor switching layer on the bottom electrode;
a top electrode on the resistor switching layer;
a cap layer adjacent to the top electrode;
a first inter-metal dielectric (IMD) layer around the cap layer;
a second IMD layer on the first IMD layer; and
a metal interconnection in the second IMD layer to connect to the top electrode.

12. The resistive random access memory of claim 11, wherein the substrate comprises an alignment mark region and a RRAM region, the resistive random access memory comprising:
a trench on the alignment mark region; and
the cap layer in the trench and extending to the ILD layer on the RRAM region.

13. The resistive random access memory of claim 10, wherein the first BE layer comprises metal.

14. The resistive random access memory of claim 10, wherein the second BE layer comprises metal nitride.

15. The resistive random access memory of claim 10, wherein a top surface of the first BE layer comprises a U-shape.

16. The resistive random access memory of claim 10, wherein a bottom surface of the second BE layer comprises a U-shape.

17. The resistive random access memory of claim 10, wherein sidewalls of the first BE layer and the second BE layer are aligned.
